(19) United States
(12) Patent Application Publication
(10) Pub. No.: US 2016/0233024 A1
(43) Pub. Date: Aug. 11, 2016

(54) MULTILAYER CERAMIC COMPONENT

(71) Applicant: SAMSUNG ELECTRO-MECHANICS CO., LTD., Suwon-Si (KR)

(72) Inventors: Dong Gun KIM, Suwon-Si (KR); Young Ha KIM, Suwon-Si (KR); Jae Yeol CHOI, Suwon-Si (KR); Se Hwan BONG, Suwon-Si (KR); Young Heon OH, Suwon-Si (KR); In Ho LEE, Suwon-Si (KR)

(21) Appl. No.: 14/934,071

(22) Filed: Nov. 5, 2015

(30) Foreign Application Priority Data
Feb. 10, 2015 (KR) 10-2015-0020152

(51) Int. Cl. H01G 4/012; H01G 4/30; H05K 1/18; H01G 4/12

(52) U.S. Cl. CPC H01G 4/012; H01G 4/12; H01G 4/30; H05K 1/181; H05K 2201/10015; H05K 2201/09409

(57) ABSTRACT

A multilayer ceramic component includes a ceramic body in which a plurality of insulating layers and internal electrodes are alternately stacked. The internal electrodes include first and second internal electrodes respectively exposed to first and second end surfaces of the ceramic body with insulating layers interposed between the first and second internal electrodes. First dummy electrodes and second dummy electrodes are disposed on the insulating layers, spaced apart from the internal electrodes by a predetermined interval and exposed to the first end surface of the ceramic body. The multilayer ceramic component satisfies 0.273≦•/D≦0.636, where D is a distance between an end of the first internal electrode and the second end surface of the ceramic body, and ω is a width of the first dummy electrode.

### CROSS-REFERENCE TO RELATED APPLICATION

This application claims the benefit of priority to Korean Patent Application No. 10-2015-0020152, filed on Feb. 10, 2015 with the Korean Intellectual Property Office, the entirety of which is incorporated herein by reference.

### TECHNICAL FIELD

The present disclosure relates to a multilayer ceramic component and a board having the same.

### BACKGROUND

Generally, electronic components that include a ceramic material, such as capacitors, inductors, varistors, thermistors, piezoelectric elements, and the like, include a ceramic body formed of a ceramic material, internal electrodes formed in an interior of the ceramic body, and external electrodes disposed on external surfaces of the ceramic body to be connected to the internal electrodes.

Among multilayer ceramic components, a multilayer ceramic capacitor includes a plurality of stacked insulating layers, internal electrodes disposed to face each other with respective insulating layers interposed therebetween, and external electrodes electrically connected to the internal electrodes.

### SUMMARY

One aspect of the present disclosure provides a multilayer ceramic component in which a shape of a ceramic body may be improved through improvement of a step portion occurring due to a thickness difference of an internal electrode with respect to an insulating layer on which the internal electrode is formed, and a board having the same.

According to an aspect of the present disclosure, a multilayer ceramic component comprises a ceramic body in which a plurality of insulating layers and internal electrodes are alternately stacked. The internal electrodes include first and second internal electrodes respectively exposed to first and second end surfaces of the ceramic body with insulating layers interposed between the first and second internal electrodes. First dummy electrodes are disposed on the insulating layers on which the first internal electrodes are disposed, spaced apart from the first internal electrodes by a predetermined interval and exposed to the second end surface of the ceramic body. Second dummy electrodes are disposed on the insulating layers on which the second internal electrodes are disposed, spaced apart from the second internal electrodes by a predetermined interval and exposed to the first end surface of the ceramic body. The multilayer ceramic component satisfies 0.273≦ω/D≦0.636, where D is a distance between an end of the first internal electrode and the second end surface of the ceramic body, and ω is a width of the first dummy electrode.

The first and second internal electrodes may comprise a capacitance forming portion formed by overlapping internal electrodes adjacent to each other to form a capacitance, and lead portions extending from the capacitance forming portion and exposed to the end surfaces of the ceramic body, respectively, wherein 0.970≦T₂/T₁≦0.982, where T₁ is a maximum thickness of the ceramic body in a region in which the capacitance forming portion is located, and T₂ is a minimum thickness of the ceramic body in a region in which the lead portions are located.

The multilayer ceramic component may satisfy 2.0≦Aₜ/A_{b}≦10.0, where A_{b} is a warpage height of a lowermost internal electrode among the plurality of internal electrodes , and Aₜ is a warpage height of an uppermost internal electrode among the plurality of internal electrodes.

Bending angles of end portions of the internal electrodes exposed to the end surface of the ceramic body with respect to the end surface of the ceramic body may be between 75° and 95°.

Each of the first and second dummy electrodes may have a length shorter than a width of the internal electrode.

The multilayer ceramic component may satisfy 0.380≦l/w≦0.761, where w is a width of the internal electrode, and l is a length of the first and second dummy electrodes.

### BRIEF DESCRIPTION OF DRAWINGS

The above and other aspects, features and other advantages of the present disclosure will be more clearly understood from the following detailed description taken in conjunction with the accompanying drawings.

FIG. 1 is a partially cut-away perspective view illustrating a multilayer ceramic component according to an exemplary embodiment in the present disclosure.

FIG. 2 is an exploded perspective view of a ceramic body of a multilayer ceramic component according to an exemplary embodiment in the present disclosure.

FIG. 3 is a plan view illustrating an internal electrode and a dummy electrode of a multilayer ceramic component according to an exemplary embodiment in the present disclosure.

FIG. 4 is a cross-sectional view taken along line I-I′ of FIG. 1.

FIG. 5 is a cross-sectional view in a length-thickness (L-T) direction of a multilayer ceramic component according to another exemplary embodiment in the present disclosure.

FIG. 6 is a plan view illustrating an internal electrode and a dummy electrode of a multilayer ceramic component according to another exemplary embodiment in the present disclosure.

FIG. 7 is a perspective view illustrating that the multilayered ceramic electronic component of FIG. 1 is mounted on a circuit board.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Multilayer Ceramic Component

An exemplary embodiment in the present disclosure relates to a multilayer ceramic component, and electronic components using ceramic materials include capacitors, inductors, piezoelectric elements, varistors, thermistors and the like. Hereinafter, a multilayer ceramic capacitor will be described as an example of the multilayer ceramic component.

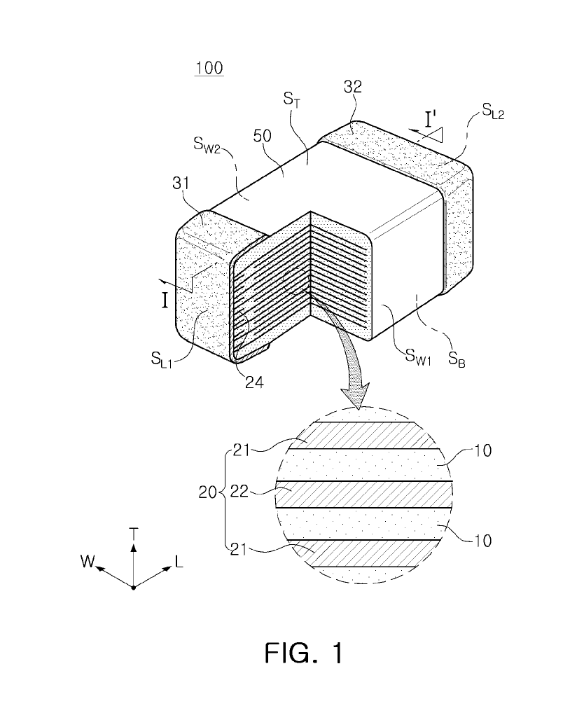

FIG. 1 is a partially cut-away perspective view illustrating a multilayer ceramic component according to an exemplary embodiment in the present disclosure.

Referring to FIG. 1, a multilayer ceramic component 100 according to an exemplary embodiment in the present disclosure includes a ceramic body in which a plurality of insulating layers 10 and internal electrodes 20 are alternately stacked. First and second external electrodes 31 and 32 are formed on external surfaces of the ceramic body 50, and electrically connected to the internal electrodes 20.

In the multilayer ceramic component 100 according to an exemplary embodiment in the present disclosure, a ‘length direction’ refers to an ‘L’ direction of FIG. 1, a ‘width direction’ refers to a ‘W’ direction of FIG. 1, and a ‘thickness direction’ refers to a ‘T’ direction of FIG. 1.

The ceramic body 50 has a first main surface S_{T} and a second main surface S_{B} opposing each other in a thickness T direction, a first side surface S_{W1} and a second side surface S_{W2} opposing each other in a width W direction, and a first end surface S_{L1} and a second end surface S_{L2} opposing each other in a length L direction.

The ceramic body 50 includes insulating layers 10, and first internal electrodes 21 and second internal electrodes 22 disposed to face each other with respective insulating layers 10 interposed therebetween.

The insulating layer 10 may include dielectric materials having a high dielectric constant, for example, a barium titanate (BaTiO₃)-based or strontium titanate (SrTiO₃)-based dielectric material, but is not limited thereto, and any materials with which a sufficient amount of capacitance may be obtained may be used.

The insulating layer 10 may be formed by including a barium titanate (BaTiO₃)-based dielectric material, and according to the purpose in the present disclosure, further including various ceramic additives, plasticizers, binders, dispersants, and the like.

The thickness of the insulating layer 10 is not particularly limited, and for example, may be 1 μm or less.

The insulating layer 10 may be stacked in an amount of 300 layers or more for implementing ultra high capacitance, but is not limited thereto.

A plurality of insulating layers 10 are in a sintered state, and boundaries between adjacent insulating layers 10 may be integrated, such that it may be difficult to identify individual layers without the use of a scanning electron microscope (SEM).

The first and second internal electrodes 21 and 22 are alternately stacked with respective insulating layers 10 interposed therebetween, and exposed to the first and second end surfaces S_{L1} and S_{L2}, of the ceramic body 50 respectively.

The first internal electrodes 21 exposed to the first end surface S_{L1} are connected to a first external electrode 31, and the second internal electrodes 22 exposed to the second end surface S_{L2} are connected to a second external electrode 32.

The first and second internal electrodes 21 and 22 may be formed by including, for example, a noble metal material such as palladium (Pd), a palladium-silver (Pd-Ag) alloy or the like, and a conductive metal such as nickel (Ni), copper (Cu) or the like.

The first and second external electrodes 31 and 32 may be formed by including, for example, a single metal such as copper (Cu), nickel (Ni), palladium (Pd), platinum (Pt), gold (Au), silver (Ag), iron (Fe), titanium (Ti) or carbon (C), or alloys thereof.

The multilayer ceramic component 100 according to an exemplary embodiment in the present disclosure includes dummy electrodes 24 not contributing to capacitance, in addition to the internal electrodes 20.

A multilayer ceramic component formed by alternately stacking insulating layers and internal electrodes may have a step difference due to the thickness of the internal electrode, thereby being formed to have an overall convex shape, in which a middle portion is thicker than an edge portion, rather than have a hexahedral shape.

An overall convex shape may lead to defects, including a tilting defect wherein the multilayer ceramic component tilts over in a taping pocket, such that it may not be grasped in the course of mounting on a board, or a tombstone defect in which the multilayer ceramic component tilts over due to surface tension of the solder.

According to an exemplary embodiment in the present disclosure, when dummy electrodes 24 not contributing to a capacitance are formed, the above described problems may be alleviated.

Shapes of the dummy electrodes 24 and the ceramic body 50 according to an exemplary embodiment in the present disclosure will be described in detail below.

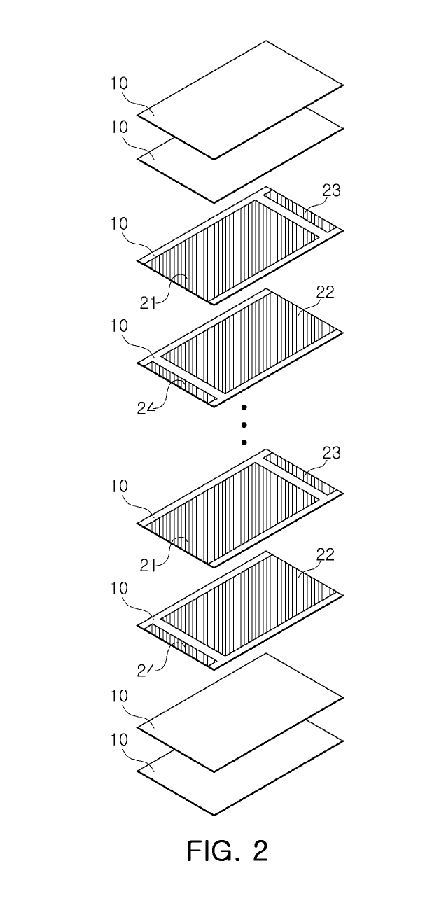

FIG. 2 is an exploded perspective view of a ceramic body of a multilayer ceramic component according to an exemplary embodiment in the present disclosure.

Referring to FIG. 2, the multilayer ceramic component 100 includes first dummy electrodes 23 disposed on insulating layers 10 on which the first internal electrodes 21 are disposed, to be spaced apart from the first internal electrodes 21 by a predetermined interval. Second dummy electrodes 24 are disposed on insulating layers 10 on which the second internal electrodes 22 are disposed, to be spaced apart from the second internal electrode 22 by a predetermined interval.

The first and second dummy electrodes 23 and 24 neither contact the first and second internal electrodes 21 and 22, nor contribute to capacitance formation.

The first dummy electrodes 23 are exposed to a second end surface S_{L2} of the ceramic body 50, and the second dummy electrodes 24 are exposed to a first end surface S_{L1} of the ceramic body 50.

Though the first and the second dummy electrodes 23 and 24 do not contribute to capacitance formation, they improve a step difference due to a thickness of the internal electrode, so that the ceramic body may have a shape close to hexahedral. Accordingly, the defects described above may be prevented.

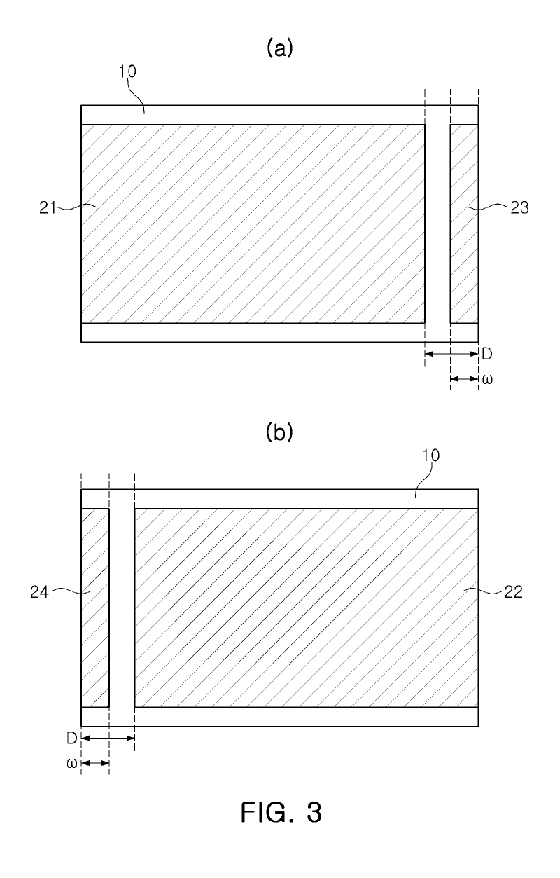

FIG. 3 is a plan view illustrating an internal electrode and a dummy electrode of a multilayer ceramic component according to an exemplary embodiment in the present disclosure.

Referring to FIG. 3, when a distance between an end of the first internal electrode 21 and the second end surface S_{L2} of the ceramic body 50, or a distance between an end of the second internal electrode 22 and the first end surface S_{L1} of the ceramic body 50 is D, and a width of the first dummy electrode 23 or the second dummy electrode 24 is ω, 0.273≦ω/D≦0.636 is satisfied.

When ω/D is less than 0.273, a width of the dummy electrode is overly small, and thus, an effect of improving a step difference of the internal electrode is insufficient, such that it may be difficult to improve a shape of the ceramic body, and a tombstone defect may occur. Further, a delamination defect between the insulating layer and the internal electrode may occur, and bending of an end portion of the internal electrode exposed to the end surface of the ceramic body is increased, thereby decreasing electrical connectivity and increasing internal electrode contact resistance.

Meanwhile, when ω/D is greater than 0.636, the width of the dummy electrode is unduly large as compared to an interval between the internal electrode and the end surface, and thus, a short defect due to connection of the internal electrode and the dummy electrode, and a delamination defect between the insulating layer and the internal electrode may occur.

In an exemplary embodiment in the present disclosure, a ratio (ω/D) of a width ω of the dummy electrodes 23 and 24 to a distance D between the end portion of the internal electrodes 21 and 22 and the end surfaces S_{L1} and S_{L2} satisfies 0.273 to 0.636, thereby preventing the tombstone defect, a short defect and a delamination defect, improving electrical connectivity, and decreasing connection resistance.

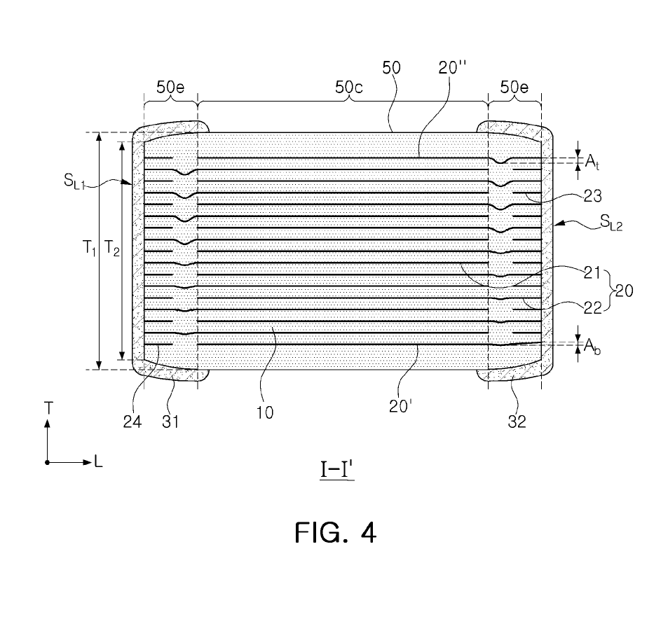

FIG. 4 is a cross-sectional view taken along line I-I′ of FIG. 1.

Referring to FIG. 4, the first and the second internal electrodes 21 and 22 include a capacitance forming portion in which adjacent internal electrodes are overlapped to form capacitance, and a lead portion extended from the capacitance forming portion and exposed to the end surfaces S_{L1} and S_{L2} of the ceramic body 50.

The lead portion is not particularly limited, but, for example, has a length shorter than a length of the internal electrode forming the capacitance forming portion in a length direction L of the ceramic body 50.

In an exemplary embodiment in the present disclosure, when a maximum thickness of the ceramic body 50c in a region in which the capacitance forming portion of the internal electrode 20 is located is T₁, and a minimum thickness of the ceramic body 50e in a region in which the lead portion is located is T₂, 0.970≦T₂/T₁≦0.982 satisfied.

When T₂/T₁ is less than 0.970, the ceramic body has a convex shape in which a middle portion thereof is thicker than an edge portion thereof, rather than have a hexahedral shape. Thus, a defect where a multilayer ceramic component is not grasped at the time of mounting the multilayer ceramic component on a board or a tombstone defect may occur.

When T₂/T₁ is greater than 0.982, the ceramic body may have a shape close to a hexahedron, but the width ω of the dummy electrode is overly large. Thus, a short defect and a delamination defect between the insulating layer and the internal electrode may occur.

In an exemplary embodiment in the present disclosure, the width ω of the dummy electrodes 23 and 24 may be in a range of 0.273≦ω/D≦0.636, so that the ceramic body 50 has a shape satisfying 0.970≦T₂/T₁≦0.982. The thus-formed ceramic body 50 has a shape close to a hexahedron, thereby preventing defects in the course of grasping a multilayer ceramic component at the time of mounting the multilayer ceramic component on a board, and tombstone defects.

In the course of stacking and sintering the insulating layers and the internal electrodes, the internal electrodes may be deformed and occupy a space in which an electrode pattern is not formed between the internal electrode and the dummy electrode. Herein, a height difference between the most concave portion and the most convex portion in the warping portion of the internal electrode may be defined as a warpage height Aₜ and A_{b}.

The warpage of the internal electrodes has increased height toward the internal electrode disposed on the upper portion, and has increased height as the width ω of the dummy electrode is increased.

In the multilayer ceramic component 100 according to an exemplary embodiment in the present disclosure, when a warpage height of the internal electrode 20′ disposed in a lowermost position among the plurality of stacked internal electrodes 20 is A_{b}, and a warpage height of the internal electrode 20″ disposed in an uppermost position among the plurality of stacked internal electrodes 20 is Aₜ, 2.0≦Aₜ/A_{b}≦10.0 is satisfied.

When a ratio of Aₜ/A_{b} is less than 2.0, a warpage defect of the internal electrode does not occur significantly, but the width ω of the dummy electrode may be overly small, so that an effect of improving a step difference of the internal electrode is insufficient. Thus, it may be difficult to improve a shape of the ceramic body, and a tombstone defect may occur. Furthermore, a delamination defect between the insulating layer and the internal electrode may occur.

When Aₜ/A_{b} is greater than 10.0, a warpage defect of the internal electrode disposed on the upper portion may occur excessively. Thus, a delamination defect between the insulating layer and the internal electrode may occur.

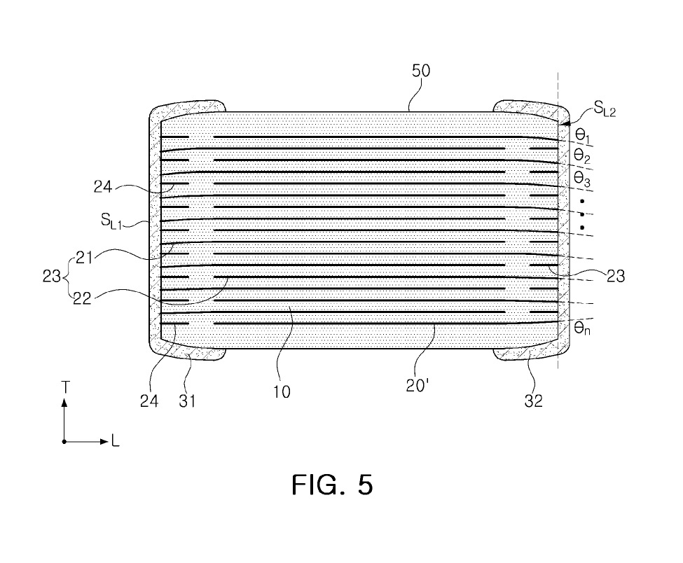

FIG. 5 is a cross-sectional view in a length-thickness (L-T) direction of a multilayer ceramic component according to another exemplary embodiment in the present disclosure.

Referring to FIG. 5, in an exemplary embodiment in the present disclosure, the bending angle formed by the end portion of the internal electrode 20 exposed to the end surfaces S_{L1} and S_{L2} of the ceramic body 50 and the end surfaces S_{L1} and S_{L2} of the ceramic body satisfies 75° to 95°.

When the dummy electrode is not formed, a lead portion of the internal electrode disposed in a region in which density of an electrode pattern is low, bends downwardly in the course of stacking and sintering the insulating layer and the internal electrode.

A bending degree of the internal electrode is increased toward upper internal electrodes. A bending angle of the internal electrode when the internal electrode does not almost bend is about 90°, and as the bending degree is increased, the bending angle is decreased.

In an exemplary embodiment in the present disclosure, by forming the first and the second dummy electrodes 23 and 24 as described above, the bending of the internal electrode may be prevented, and the decrease of bending angle may be reduced.

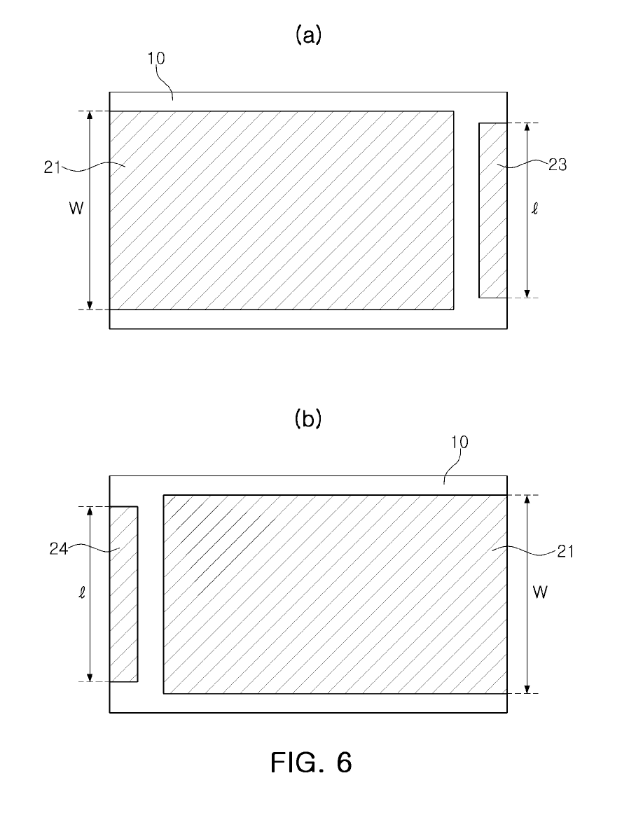

FIG. 6 is a plan view illustrating an internal electrode and a dummy electrode of a multilayer ceramic component according to another exemplary embodiment in the present disclosure.

Referring to FIG. 6, the multilayer ceramic component 100 according to another exemplary embodiment in the present disclosure has the first and the second dummy electrodes 23 and 24 each having a length l shorter than the width w of the first or the second internal electrode 21 or 22.

By forming the length of the first or the second dummy electrode 23 or 24 to be shorter than the width w of the first or the second internal electrode 21 or 22, an area of the electrode pattern exposed to an external surface of the ceramic body may be decreased to reduce cracks in the ceramic body occurring in the course of plating the external electrode.

A ratio l/w of the length k of the first or the second dummy electrode 23 or 24 to the width w of the first or the second internal electrode 21 or 22 may satisfy 0.380≦l/w≦0.761.

When l/w is less than 0.380, the length of the dummy electrode is overly short. Thus, an effect of improving step difference of the internal electrode is insufficient, such that it may be difficult to improve a shape of the ceramic body, and a tombstone defect may occur. Furthermore, a delamination defect between the insulating layer and the internal electrode may occur.

When l/w is greater than 0.761, an area of the electrode pattern exposed to external surfaces of the ceramic body is large, so that a defect of cracks in the ceramic body in the course of plating the external electrode may occur.

The constitutions overlapped with the constitutions of the multilayer ceramic component according to the exemplary embodiment in the present disclosure described above are identically applicable, excepting the length l of the first and the second dummy electrodes 23 and 24.

### Board Having Electronic Component

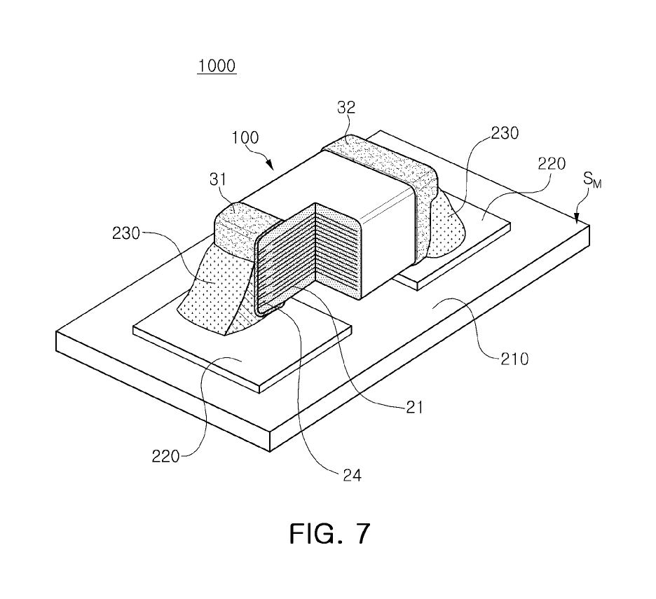

FIG. 7 is a perspective view illustrating the multilayered ceramic electronic component of FIG. 1 mounted on a circuit board.

Referring to FIG. 7, a board 1000 on which the multilayer ceramic component 100 according to an exemplary embodiment in the present disclosure is provided includes a circuit board 210 including a plurality of electrode pads 220 spaced apart from each other on the upper portion, and the multilayer ceramic component 100 mounted on the circuit board 210.

Each of the first and the second external electrodes 31 and 32 disposed on external surfaces of the multilayer ceramic component 100 may be soldered by solder 230 in a state disposed to be in contact with on the electrode pad 220, thereby being electrically connected to the circuit board 210.

Herein, the multilayer ceramic component 100 according to an exemplary embodiment in the present disclosure includes the first and the second dummy electrodes 23 and 24 formed as described above, thereby improving the step difference due to the thickness of the internal electrode so that the shape of the ceramic body may be formed closely to a hexahedron. Accordingly, the tombstone defect occurring when the multilayer ceramic component 100 tilts due to surface tension of the solder 230 to be raised at the time of mounting the multilayer ceramic component 100 on the circuit board 210 may be prevented.

Meanwhile, FIG. 7 only illustrates that the internal electrode 20 of the multilayer ceramic component 100 is mounted to be disposed horizontally to amounted surface Sₘ of the circuit board 210, but is not limited thereto, and it is also possible to mount the internal electrode 20 to be disposed vertically to the mounted surface Sₘ of the circuit board 210.

Descriptions overlapped with descriptions of the electronic component according to an exemplary embodiment in the present disclosure described above except the above description will be omitted herein.

Following Table 1 represents changed distances D between the end portion of the internal electrode 20 and the end surface S_{L1}, S_{L2} of the ceramic body and widths ω of the dummy electrode, along with the results of measuring 1) the ratio ω/D of the width ω of the dummy electrode to the distance D between the end portion of the internal electrode and the end surface, 2) the ratio T₂/T₁ of the minimum thickness T₂ of the ceramic body 50e in a region in which the lead portion of the internal electrode is positioned to the maximum thickness T₁ of the ceramic body 50c in a region in which the capacitance forming portion of the internal electrode is positioned, and 3) the ratio Aₜ/A_{b} of the warpage height Aₜ of the internal electrode 20_{b} of the internal electrode 20′ disposed in a lowermost position.

Further, following Table 2 represents the thus-measured values of the tombstone defect, the short defect, and the delamination defect.

TABLE 1

| | ω(mm) | D(mm) | ω/D | T₂/T₁ | Aₜ(μm) | A_{b}(μm) | Aₜ/A_{b} |
|---|---|---|---|---|---|---|---|
| 1* | 0.000 | 0.110 | 0.000 | 0.932 | 1.7 | 1.1 | 1.5 |
| 2* | 0.005 | 0.110 | 0.045 | 0.935 | 1.8 | 1.1 | 1.6 |
| 3* | 0.010 | 0.110 | 0.091 | 0.937 | 1.8 | 1.2 | 1.5 |
| 4* | 0.015 | 0.110 | 0.136 | 0.941 | 2.0 | 1.2 | 1.7 |
| 5* | 0.020 | 0.110 | 0.182 | 0.943 | 2.1 | 1.2 | 1.8 |
| 6* | 0.025 | 0.110 | 0.227 | 0.942 | 2.4 | 1.3 | 1.8 |
| 7 | 0.030 | 0.110 | 0.273 | 0.970 | 2.6 | 1.3 | 2.0 |
| 8 | 0.035 | 0.110 | 0.318 | 0.975 | 2.8 | 1.3 | 2.2 |
| 9 | 0.040 | 0.110 | 0.364 | 0.973 | 3.1 | 1.4 | 2.2 |
| 10 | 0.045 | 0.110 | 0.409 | 0.976 | 5.2 | 1.4 | 3.7 |
| 11 | 0.050 | 0.110 | 0.455 | 0.974 | 6.4 | 1.4 | 4.6 |
| 12 | 0.055 | 0.110 | 0.500 | 0.977 | 8.9 | 1.5 | 5.9 |
| 13 | 0.060 | 0.110 | 0.545 | 0.975 | 11.2 | 1.5 | 7.5 |
| 14 | 0.065 | 0.110 | 0.591 | 0.978 | 13.8 | 1.5 | 9.2 |
| 15 | 0.070 | 0.110 | 0.636 | 0.982 | 15.0 | 1.5 | 10.0 |
| 16* | 0.075 | 0.110 | 0.682 | 0.983 | 16.8 | 1.5 | 11.2 |
| 17* | 0.080 | 0.110 | 0.727 | 0.989 | 16.9 | 1.6 | 10.6 |
| 18* | 0.085 | 0.110 | 0.773 | 0.920 | 16.9 | 1.6 | 10.6 |
| 19* | 0.090 | 0.110 | 0.818 | 0.994 | 17.5 | 1.6 | 10.9 |
| 20* | 0.095 | 0.110 | 0.864 | 0.996 | 17.7 | 1.7 | 10.4 |
| 21* | 0.100 | 0.110 | 0.909 | 0.998 | 17.8 | 1.7 | 10.5 |
| 22* | 0.105 | 0.110 | 0.955 | 0.998 | 18.0 | 1.7 | 10.6 |
| 23* | 0.110 | 0.110 | 1.000 | 1.000 | 18.1 | 1.7 | 10.6 |

(*Comparative Examples)

TABLE 2

| | Incidence | Incidence | Incidence |
|---|---|---|---|
| | of tombstone | of short | of delamination |
| | defect (ppm) | defect (%) | defect (ppm) |
| 1* | 1.3 | 3.3 | 3.9 |
| 2* | 0.6 | 3.6 | 4.0 |
| 3* | 0.4 | 3.0 | 2.9 |
| 4* | 0.2 | 3.3 | 3.1 |
| 5* | 0.1 | 3.5 | 2.2 |
| 6* | 0.0 | 3.4 | 1.3 |
| 7 | 0.0 | 3.2 | 0.0 |
| 8 | 0.0 | 3.8 | 0.0 |
| 9 | 0.0 | 3.4 | 0.0 |
| 10 | 0.0 | 3.4 | 0.0 |
| 11 | 0.0 | 3.6 | 0.0 |
| 12 | 0.0 | 3.7 | 0.0 |
| 13 | 0.0 | 3.2 | 0.0 |
| 14 | 0.0 | 3.6 | 0.0 |
| 15 | 0.0 | 3.3 | 0.0 |
| 16* | 0.0 | 3.5 | 2.3 |
| 17* | 0.0 | 97.3 | 2.6 |
| 18* | 0.0 | 98.1 | 2.5 |
| 19* | 0.0 | 98.3 | 2.9 |
| 20* | 0.0 | 98.7 | 3.3 |
| 21* | 0.0 | 99.6 | 3.8 |
| 22* | 0.0 | 99.8 | 3.5 |
| 23* | 0.0 | 100.0 | 3.9 |

(*Comparative Examples)

Following Table 3 represents changed width W of the internal electrode and length l of the dummy electrode, along with the ratio l/W of the length l of the dummy electrode to the width W of the internal electrode, and the thus-measured values of the tombstone defect, the delamination defect, and the crack defect occurring in the plating.

TABLE 3

| | | | | Incidence | Incidence | Incidence |
|---|---|---|---|---|---|---|
| | | | | of | of | of crack |
| | | | | tombstone | delamination | during |
| | | | | defect | defect | plating |
| | l(mm) | W(mm) | l/W | (ppm) | (ppm) | (ppm) |
| 24* | 0.000 | 0.920 | 0.000 | 1.8 | 3.7 | 214 |
| 25* | 0.050 | 0.920 | 0.054 | 1.6 | 3.4 | 320 |
| 26* | 0.100 | 0.920 | 0.109 | 1.2 | 3.1 | 348 |
| 27* | 0.150 | 0.920 | 0.163 | 0.9 | 2.6 | 480 |
| 28* | 0.200 | 0.920 | 0.217 | 0.4 | 2.2 | 383 |
| 29* | 0.250 | 0.920 | 0.272 | 0.1 | 1.8 | 328 |
| 30* | 0.300 | 0.920 | 0.326 | 0.0 | 1.1 | 421 |
| 31 | 0.350 | 0.920 | 0.380 | 0.0 | 0 | 385 |
| 32 | 0.400 | 0.920 | 0.435 | 0.0 | 0 | 395 |
| 33 | 0.450 | 0.920 | 0.489 | 0.0 | 0 | 445 |
| 34 | 0.500 | 0.920 | 0.543 | 0.0 | 0 | 368 |
| 35 | 0.550 | 0.920 | 0.598 | 0.0 | 0 | 351 |
| 36 | 0.600 | 0.920 | 0.652 | 0.0 | 0 | 396 |
| 37 | 0.650 | 0.920 | 0.707 | 0.0 | 0 | 299 |
| 38 | 0.700 | 0.920 | 0.761 | 0.0 | 0 | 375 |
| 39* | 0.750 | 0.920 | 0.815 | 0.0 | 0 | 1,633 |
| 40* | 0.800 | 0.920 | 0.870 | 0.0 | 0 | 1,486 |
| 41* | 0.850 | 0.920 | 0.924 | 0.0 | 0 | 1,657 |
| 42* | 0.900 | 0.920 | 0.978 | 0.0 | 0 | 2,186 |
| 43* | 0.950 | 0.920 | 1.033 | 0.0 | 0 | 2,853 |
| 44* | 1.000 | 0.920 | 1.087 | 0.0 | 0 | 2,354 |
| 45* | 1.050 | 0.920 | 1.141 | 0.0 | 0 | 3,285 |
| 46* | 1.100 | 0.920 | 1.196 | 0.0 | 0 | 2,975 |

(*Comparative Examples)

As set forth above, according to exemplary embodiments in the present disclosure, a shape of the ceramic body may be improved to have a shape close to that of a hexahedron by improving a step portion occurring due to a thickness difference of an internal electrode with respect to an insulating layer on which the internal electrode is formed, thereby preventing a defect occurring at the time of mounting the multilayer ceramic component on the board.

As shown in Table 2, exemplary embodiments of multilayer ceramic components have an unexpected improvement in incidences of tombstone defect, short defects, and delamination in contrast to the Comparative Examples. Also as shown in Table 3, multilayer ceramic components according to exemplary embodiments have an unexpected improvement in incidences of tombstone defect, delamination defects, and incidences of cracks during plating.

While exemplary embodiments have been shown and described above, it will be apparent to those skilled in the art that modifications and variations could be made without departing from the scope of the present invention as defined by the appended claims.

What is claimed is:

1. A multilayer ceramic component comprising:
a ceramic body in which a plurality of insulating layers and internal electrodes are alternately stacked, the internal electrodes including first and second internal electrodes respectively exposed to first and second end surfaces of the ceramic body with insulating layers interposed between the first and second internal electrodes; and
first dummy electrodes disposed on the insulating layers on which the first internal electrodes are disposed, spaced apart from the first internal electrodes by a predetermined interval and exposed to the second end surface of the ceramic body, and second dummy electrodes disposed on the insulating layers on which the second internal electrodes are disposed, spaced apart from the second internal electrodes by a predetermined interval and exposed to the first end surface of the ceramic body,
wherein 0.273≦ω/D≦0.636, where D is a distance between an end of the first internal electrode and the second end surface of the ceramic body, and ω is a width of the first dummy electrode.

2. The multilayer ceramic component of claim 1, wherein the first and second internal electrodes comprise a capacitance forming portion formed by overlapping internal electrodes adjacent to each other to form a capacitance, and lead portions extending from the capacitance forming portion and exposed to the end surfaces of the ceramic body, respectively,
wherein 0.970≦T₂/T₁≦0.982, where T₁ is a maximum thickness of the ceramic body in a region in which the capacitance forming portion is located, and T₂ is a minimum thickness of the ceramic body in a region in which the lead portions are located.

3. The multilayer ceramic component of claim 1, wherein 2.0≦Aₜ/A_{b}≦10.0, where A_{b} is a warpage height of a lowermost internal electrode among the plurality of internal electrodes, and Aₜ is a warpage height of an uppermost internal electrode among the plurality of internal electrodes.

4. The multilayer ceramic component of claim 1, wherein bending angles of end portions of the internal electrodes exposed to the end surface of the ceramic body with respect to the end surface of the ceramic body are between 75° and 95°.

5. The multilayer ceramic component of claim 1, wherein each of the first and second dummy electrodes has a length shorter than a width of the internal electrode.

6. The multilayer ceramic component of claim 1, wherein 0.380≦l/w≦0.761, where w is a width of the internal electrode, and l is a length of the first and second dummy electrodes.

7. A multilayer ceramic component comprising:
a ceramic body in which a plurality of insulating layers and internal electrodes are alternately stacked, the internal electrodes including first and second internal electrodes respectively exposed to first and second end surfaces of the ceramic body with insulating layers interposed between the first and second internal electrodes;
first dummy electrodes disposed on the insulating layers on which the first internal electrodes are disposed, spaced apart from the first internal electrodes by a predetermined interval and exposed to the second end surface of the ceramic body; and
second dummy electrodes disposed on the insulating layers on which the second internal electrodes are disposed, spaced apart from the second internal electrodes by a predetermined interval and exposed to the first end surface of the ceramic body,
wherein the first and second internal electrodes comprise a capacitance forming portion formed by overlapping internal electrodes adjacent to each other to form a capacitance, and lead portions extending from the capacitance forming portion and exposed to the end surfaces of the ceramic body, respectively, wherein 0.970≦T₂/T₁≦0.982, where T₁ is a thickness of the ceramic body in a region in which the capacitance forming portion is located, and T₂ is a thickness of the ceramic body in a region in which the lead portions are located.

8. The multilayer ceramic component of claim 7, wherein 0.273≦ω/D≦0.636, where D is a distance between an end of the first internal electrode and the second end surface of the ceramic body, and ω is a width of the first dummy electrode.

9. The multilayer ceramic component of claim 7, wherein 2.0≦Aₜ/A_{b}1≦0.0, where A_{b} is a warpage height of a lowermost internal electrode among the plurality of internal electrodes, and Aₜ is a warpage height of an uppermost internal electrode among the plurality of internal electrodes.

10. The multilayer ceramic component of claim 7, wherein bending angles of end portions of the internal electrodes exposed to the end surfaces of the ceramic body with respect to the end surface of the ceramic body are between 75° and 95°.

11. The multilayer ceramic component of claim 7, wherein 0.380≦l/w≦0.761, where w is a width of the internal electrode, and l is a length of the first or second dummy electrode.

12. A board having a multilayer ceramic component comprising:
a circuit board having a plurality of electrode pads thereon; and
the multilayer ceramic component of claim 1 mounted on the circuit board.
